(19) United States
(12) Patent Application Publication
(10) Pub. No.: US 2008/0061679 A1
(43) Pub. Date: Mar. 13, 2008

(54) Carbazolyl-Functional Polysiloxane Resins, Silicone Composition, and Organic Light-Emitting Diode

(76) Inventor: Shihe Xu, Midland, MI (US)

Correspondence Address: DOW CORNING CORPORATION CO1232, 2200 W. SALZBURG ROAD, P.O. BOX 994, MIDLAND, MI, 48686-0994, US

(21) Appl. No.: 10/566,048

(22) PCT Filed: Jun. 29, 2004
(86) PCT No.: PCT/US04/20948

§ 371 Date: Jan. 26, 2006

Related U.S. Application Data
(60) Provisional application No. 60/496,637, filed on Aug. 20, 2003.

(51) Int. Cl. H01L 51/52; C08G 77/26

(52) U.S. Cl. 313/504; 528/34

(57) ABSTRACT

Carbazolyl-functional polysiloxane resins containing N-carbazolylalkyl groups, a silicone composition containing a carbazolyl-functional polysiloxane resin, a cured carbazolyl-functional polysiloxane prepared by curing the silence composition, and an organic light-emitting diode (OLED) containing a carbazolyl-functional polysiloxane.

### FIELD OF THE INVENTION

The present invention relates to carbazolyl-functional polysiloxane resins and more particularly to carbazolyl-functional polysiloxane resins containing N-carbazolylalkyl groups. The present invention also relates to a silicone composition containing a carbazolyl-functional polysiloxane resin, a cured carbazolyl-functional polysiloxane prepared by curing the silicone composition, and an organic light-emitting diode (OLED) containing a carbazolyl-functional polysiloxane.

### BACKGROUND OF THE INVENTION

Carbazolyl-functional linear polysiloxanes containing carbazolylalkyl groups are known in the art. For example, Strohriegl (Makromol. Chem., Rapid Commun., 1986, 7, 771-775) describes the preparation and characterization of a series of polysiloxanes with pendant carbazole groups, wherein the carbazole units are separated from the siloxane backbone by alkylene spacers.

U.S. Pat. No. 4,933,053 to Tieke discloses electrically conductive polymers obtainable by anodic oxidation of starting polymers consisting of 5-100 mol % of recurring structural units of the formula I and 95-0 mol % of recurring structural units of the formula II

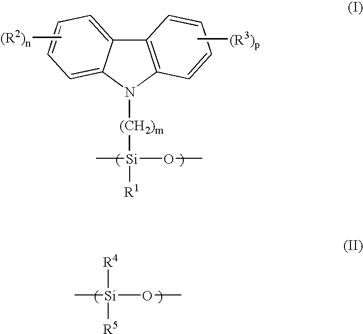

in which R¹ and R⁴ independently of one another are C₁-C₄ alkyl, C₁-C₄ alkoxy, phenyl or phenoxy, R² and R³ independently of one another are C₁-C₄ alkyl, C₁-C₄ alkoxy, halogen, cyano or nitro, R⁵ is C₁-C₁₈ alkyl, which is unsubstituted or can be substituted by one or two hydroxyl groups, or is phenyl or hydroxyl, m is an integer from 3-11, and n and p independently of one another are integers from 0 to 2. The '053 patent teaches the products are suitable especially as electrochromic display elements, as a positive electrode material or as electrically conductive films.

Derwent Abstract No.1987-158535 of European Patent Application No. EP 0224784 to Leyrer et al. discloses polysiloxanes having lateral carbazole groups attached to the main polymer chain. The Abstract teaches the polysiloxanes can be used in electrophotographic recording materials and for providing electrophotographic offset printing plates.

The Patent Abstracts of Japan publication corresponding to Japanese Patent Application No. 02127432 to Kazumasa et al. discloses a carbazole group-containing curable composition containing (A) a carbazole group-containing curable compound having a carbazole group, OH group bonded to silicon atom or hydrolysable group and silicon atom-containing group crosslinkable by forming a siloxane bond and (B) a silanol condensation catalyst.

Carbazolyl-functional cyclosiloxanes containing carbazolylalkyl groups are also known in the art. For example, Hohle and Strohriegl describe the preparation and characterization of photorefractive cyclosiloxanes (Proc. SPIE-Int. Soc. for Opt. Eng., 1999, 3796, 353-359). The cyclosiloxanes (n=3,5) were prepared via a platinum-catalyzed hydrosilylation reaction between tetramethylcylcotetrasiloxane and ω-(carbazol-9-yl)alkenes.

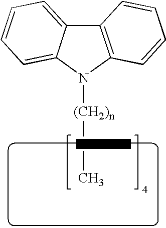

Maud et al. describe the preparation and characterization of carbazolylalkyl-substituted cyclosiloxanes (Synthetic Metals, 1993, 55-57, 890-895). The cyclosiloxanes (a: n=4, m=3; b: n=4, m=11; c: n=5, m=3) were prepared via a platinum-catalyzed hydrosilylation reaction between oligocyclomethylhydrosiloxanes and ω-(carbazol-9-yl)alk-1-enes in refluxing toluene.

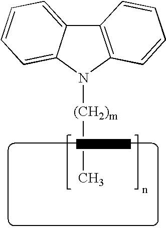

Although, the aforementioned references disclose linear polysiloxanes and cyclosiloxanes containing carbazolylalkyl groups, they do not disclose the carbazolyl-functional polysiloxane resins, silicone composition, cured carbazolyl-functional polysiloxane, or OLED of the present invention.

### SUMMARY OF THE INVENTION

The present invention is directed to a carbazolyl-functional polysiloxane resin comprising units having the formula I, units having the formula II, and units having the formula III:

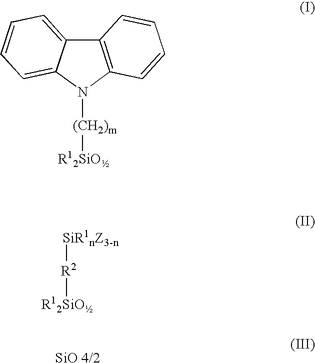

wherein R¹ is C₁ to C₁₀ hydrocarbyl free of aliphatic unsaturation; R² is —CH₂—CHR³— or —CH₂—CHR³—Y—, wherein Y is a divalent organic group and R³ is R¹ or —H; Z is a hydrolysable group; m is an integer from 2 to 10; n is 0, 1, or 2; the mole ratio of units (I) to units (II) is from 4:1 to 9:1; and the mole ratio of units (I) and units (II) combined to units (III) is from 1.2:1 to 1.8:1.

The present invention is also directed to a carbazolyl-functional polysiloxane resin comprising units having the formula I and units having the formula III:

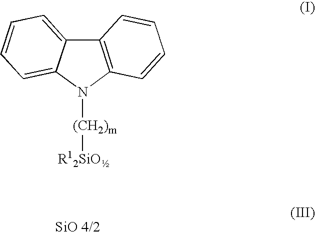

wherein R¹ is C₁ to C₁₀hydrocarbyl free of aliphatic unsaturation, m is an integer from 2 to 10, and the mole ratio of units (I) to units (III) is from 1.2:1 to 1.8:1.

The present invention is also directed to a silicone composition comprising the first-mentioned carbazolyl-functional polysiloxane resin, a condensation catalyst, and an organic solvent. The present invention is further directed to a cured carbazolyl-functional polysiloxane prepared by curing the silicone composition.

The instant invention is still further directed to an organic light-emitting diode comprising:
a substrate having a first opposing surface and a second opposing surface;
a first electrode layer overlying the first opposing surface;
a light-emitting element overlying the first electrode layer, the light emitting element comprising
   a hole-transport layer and
   an electron-transport layer, wherein the hole-transport layer and the electron-transport layer lie directly on one another, and one of the hole-transport layer and the electron-transport layer comprises a carbazolyl-functional polysiloxane selected from
      a cured carbazolyl-functional polysiloxane prepared by curing a silicone composition comprising (A) at least one carbazolyl-functional polysiloxane resin comprising units having the formula I, units having the formula II, and units having the formula III:

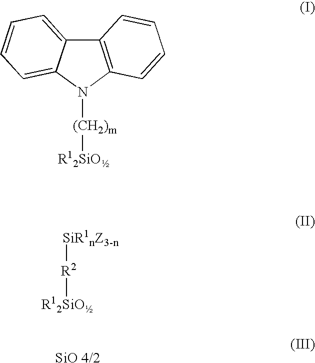

wherein R¹ is C₁ to C₁₀ hydrocarbyl free of aliphatic unsaturation, R² is —CH₂—CHR³— or —CH₂—CHR³—Y—, wherein Y is a divalent organic group and R³ is R¹ or —H, Z is a hydrolysable group, m is an integer from 2 to 10, n is 0, 1, or 2, the mole ratio of units (I) to units (II) is from 4:1 to 9:1, and the mole ratio of units (I) and units (II) combined to units (III) is from 1.2:1 to 1.8:1, (B) a condensation catalyst, and (C) an organic solvent, and
   at least one carbazolyl-functional polysiloxane resin comprising units having the formula I and units having the formula III:

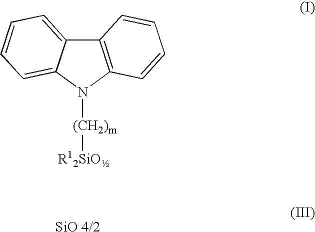

wherein R¹ is C₁ to C₁₀ hydrocarbyl free of aliphatic unsaturation, m is an integer from 2 to 10, and the mole ratio of units (I) to units (III) is from 1.2:1 to 1.8:1; and
a second electrode layer overlying the light-emitting element.

The carbazolyl-functional polysiloxane resins of the present invention exhibit electroluminescence, emitting light when subjected to an applied voltage. Moreover, the polysiloxane resin containing hydrolysable groups can be cured to produce a durable cross-linked polysiloxane. Also, the polysiloxane resins can be doped with small amounts of fluorescent agents to enhance the electroluminescent efficiency and control the color output of the polysiloxanes.

The silicone composition of the present invention can be conveniently formulated as a one-part composition. Moreover, the silicone composition has good shelf-stability in the absence of moisture. Importantly, the composition can be applied to a substrate by conventional high-speed methods such as spin coating, printing, and spraying. Also, the silicone composition can be readily cured by exposure to moisture at mild to moderate temperatures.

The cured carbazolyl-functional polysiloxane prepared by curing the silicone composition of the present invention exhibits electroluminescence. Moreover, the cured polysiloxane has good primerless adhesion to a variety of substrates. The cured polysiloxane also exhibits excellent durability, chemical resistance, and flexibility at low temperatures. Additionally, the cured polysiloxane exhibits high transparency, typically at least 95% transmittance at a thickness of 100 nm, in the visible region of the electromagnetic spectrum. Importantly, the cured polysiloxane is substantially free of acidic or basic components, which are detrimental to the electrode and light-emitting layers in OLED devices.

The OLED of the present invention exhibits good resistance to abrasion, organic solvents, moisture, and oxygen. Moreover, the OLED exhibits high quantum efficiency and photo stability.

The OLED is useful as a discrete light-emitting device or as the active element of light-emitting arrays or displays, such as flat panel displays. OLED displays are useful in a number of devices, including watches, telephones, lap-top computers, pagers, cellular phones, digital video cameras, DVD players, and calculators.

These and other features, aspects, and advantages of the present invention will become better understood with reference to the following description, appended claims, and accompanying drawing.

### BRIEF DESCRIPTION OF THE DRAWINGS

FIG. 1 shows a cross-sectional view of a first embodiment of an OLED according to the present invention.

FIG. 2 shows a cross-sectional view of a second embodiment of an OLED according to the present invention.

FIG. 3 shows a cross-sectional view of a third embodiment of an OLED according to the present invention.

FIG. 4 shows a cross-sectional view of a fourth embodiment of an OLED according to the present invention.

### DETAILED DESCRIPTION OF THE INVENTION

As used herein, the term “hydrocarbyl group free of aliphatic unsaturation” means the group is free of aliphatic carbon-carbon double bonds and aliphatic carbon-carbon triple bonds. Also, the term “N-carbazolyl” refers to a group having the formula:

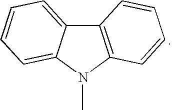

A first carbazolyl-functional polysiloxane resin according to the present invention comprises units having the formula I, units having the formula II, and units having the formula III:

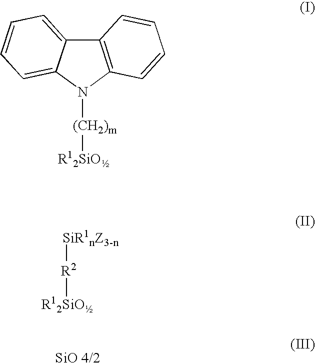

wherein R¹ is C₁ to C₁₀ hydrocarbyl free of aliphatic unsaturation; R² is —CH₂—CHR³— or —CH₂—CHR³—Y—, wherein Y is a divalent organic group and R³ is R¹ or —H; Z is a hydrolysable group; m is an integer from 2 to 10; n is 0, 1, or 2; the mole ratio of units (I) to units (II) is from 4:1 to 9:1; and the mole ratio of units (I) and units (II) combined to units (III) is from 1.2:1 to 1.8:1. Alternatively, the subscript m has a value of from 3 to 10 or from 3 to 6.

The hydrocarbyl groups represented by R¹ are free of aliphatic unsaturation and typically have from 1 to 10 carbon atoms, alternatively from 1 to 6 carbon atoms. Acyclic hydrocarbyl groups containing at least 3 carbon atoms can have a branched or unbranched structure. Examples of hydrocarbyl groups include, but are not limited to, alkyl, such as methyl, ethyl, propyl, 1-methylethyl, butyl, 1-methylpropyl, 2-methylpropyl, 1,1-dimethylethyl, pentyl, 1-methylbutyl, 1-ethylpropyl, 2-methylbutyl, 3-methylbutyl, 1,2-dimethylpropyl, 2,2-dimethylpropyl, hexyl, heptyl, octyl, nonyl, decyl, undecyl, dodecyl, tridecyl, tetradecyl, pentadecyl, hexadecyl, heptadecyl, and octadecyl; cycloalkyl, such as cyclopentyl, cyclohexyl, and methylcyclohexyl; aryl, such as phenyl and naphthyl; alkaryl, such as tolyl and xylyl; and aralkyl, such as benzyl and phenethyl.

The divalent organic groups represented by Y typically have from 1 to 18 carbon atoms, alternatively from 1 to 10 carbon atoms, alternatively from 1 to 6 carbon atoms. In addition to carbon and hydrogen, the divalent organic groups may contain other atoms such as nitrogen, oxygen, and halogen, provided the divalent group does not inhibit the hydrosilylation reaction, described below, used to prepare the polysiloxane or react with the hydrolysable group Z in the polysiloxane. Examples of divalent organic groups represented by Y include, but are not limited to, hydrocarbylene such as methylene, propylene, and phenylene; halo-substituted hydrocarbylene such as chloroethylene and fluoroethylene; and alkyleneoxyalkylene such as —CH₂OCH₂CH₂CH₂—, —CH₂CH₂OCH₂CH₂—, —CH₂CH₂OCH(CH₃)CH₂—, and —CH₂OCH₂CH₂OCH₂CH₂—; and carbonyloxyalkylene, such as —C(═O)O—(CH₂)₃—.

As used herein, the term “hydrolysable group” means the silicon-bonded group Z can react with water to form a silicon-bonded —OH (silanol) group. Examples of hydrolysable groups represented by Z include, but are not limited to, —Cl, Br, —OR⁴, —OCH₂CH₂OR⁴, CH₃C(═O)O—, Et(Me)C═N—O—, CH₃C(═O)N(CH₃)—, and —ONH₂, wherein R⁴ is C₁ to C₈ hydrocarbyl or halogen-substituted hydrocarbyl, both free of aliphatic unsaturation.

Examples of hydrocarbyl groups represented by R⁴ include, but are not limited to, unbranched and branched alkyl, such as methyl, ethyl, propyl, 1-methylethyl, butyl, 1-methylpropyl, 2-methylpropyl, 1,1-dimethylethyl, pentyl, 1-methylbutyl, 1-ethylpropyl, 2-methylbutyl, 3-methylbutyl, 1,2-dimethylpropyl, 2,2-dimethylpropyl, hexyl, heptyl, and octyl; cycloalkyl, such as cyclopentyl, cyclohexyl, and methylcyclohexyl; phenyl; alkaryl, such as tolyl and xylyl; and aralkyl, such as benzyl and phenethyl. Examples of halogen-substituted hydrocarbyl groups include, but are not limited to, 3,3,3-trifluoropropyl, 3-chloropropyl, chlorophenyl, and dichlorophenyl.

The first carbazolyl-functional polysiloxane resin is a copolymer comprising units having formulae (I), (II), and (III), above. The mole ratio of units (I) to units (II) is typically from 4:1 to 9:1, alternatively from 6:1 to 9:1, alternatively from 7:1 to 9:1. The mole ratio of units (I) and units (II) combined to units (III) is typically from 1.2:1 to 1.8:1, alternatively from 1.4:1 to 1.8:1, alternatively from 1.6:1 to 1.8:1.

Examples of the first carbazolyl-functional polysiloxane resin include, but are not limited to, polysiloxane resins having the following average formulae: [Me₂(CzCH₂CH₂CH₂) SiO_{1/2}]_{1.56}[Me₂(CH₂CH₂Si(OMe)₃)SiO_{1/2}]_{0.24} (SiO_{4/2}), [Me₂(CzCH₂CH₂CH₂) SiO_{1/2}]_{1.57}[Me₂(CH₂CH₂CH₂Si(OMe)₃)SiO_{1/2}]_{0.23}(SiO_{4/2}), [Et₂(CzCH₂CH₂CH₂) SiO_{1/2}]_{1.6}[Et₂(CH₂CH₂CH₂Si(OMe)₃)SiO_{1/2}]_{0.2} (SiO_{4/2}), [Me₂(CzCH₂CH₂CH₂) SiO_{1/2}]_{1.62}[Me₂(CH₂CH(Me)CO₂CH₂CH₂CH₂Si(OMe)₃)SiO_{1/2}]_{0.18} (SiO_{4/2}), [Me₂(CzCH₂CH₂CH₂) SiO_{1/2}]_{1.4}[Me₂(CH₂CH₂Si(OMe)₃)SiO_{1/2}]_{0.2} (SiO_{4/2}), [Me₂(CzCH₂CH₂CH₂) SiO_{1/2}]_{1.42}[Me₂(CH₂CH₂CH₂Si(OMe)₃)SiO_{1/2}]_{0.18}(SiO_{4/2}), [Et₂(CzCH₂CH₂CH₂) SiO_{1/2}]_{1.44}[Et₂(CH₂CH₂CH₂Si(OMe)₃)SiO_{1/2}]_{0.16}(SiO_{4/2}), [Me₂(CzCH₂CH₂CH₂) SiO_{1/2}]_{1.22}[Me₂(CH₂CH₂Si(OMe)₃)SiO_{1/2}]_{0.18} (SiO_{4/2}), [Me₂(CzCH₂CH₂CH₂) SiO_{1/2}]_{1.24}[Me₂(CH₂CH₂CH₂Si(OMe)₃)SiO_{1/2}]_{0.16}(SiO_{4/2}), and [Me₂(CzCH₂CH₂CH₂) SiO_{1/2}]_{1.26}[Me₂(CH₂CH(Me)CO₂CH₂CH₂CH₂Si(OMe)₃)SiO_{1/2}]_{0.14} (SiO_{4/2}), where Me is methyl, Et is ethyl, and the numerical subscripts denote the relative number of moles of the units.

The first carbazolyl-functional polysiloxane resin can be prepared by reacting (a) an organohydrogenpolysiloxane resin consisting essentially of HR¹₂SiO_{1/2} units and SiO_{4/2} units wherein the mole ratio of HR¹₂SiO_{1/2} units to SiO_{4/2} units is from 1.2:1 to 1.8:1, with (b) an N-alkenyl carbazole having the formula Cz-(CH₂)ₘ₋₂—CH═CH₂ and (c) an alkenyl silane having a formula selected from Z₃₋ₙR¹ₙSi—Y—CR³═CH₂ and Z₃₋ₙR¹ₙSi—CR³═CH₂ in the presence of (d) a hydrosilylation catalyst and, optionally, (e) an organic solvent, wherein Cz is N-carbazolyl and R¹, R³, Y, Z, m, and n are as defined and exemplified above for the first carbazolyl-functional polysiloxane resin.

Organohydrogenpolysiloxane resin (a) consists essentially of HR¹₂SiO_{1/2} units and SiO_{4/2} units wherein the mole ratio of HR¹₂SiO_{1/2} units to SiO_{4/2} units is from 1.2:1 to 1.8:1, alternatively from 1.4:1 to 1.8:1, alternatively from 1.6:1 to 1.8:1.

Examples of organohydrogenpolysiloxane resins suitable for use as organohydrogenpolysiloxane resin (a) include, but are not limited to, polysiloxane resins having the following average formulae: (HMe₂SiO_{1/2})_{1.2}(SiO_{4/2}), (HMe₂SiO_{1/2})_{1.4}(SiO_{4/2}), (HMe₂SiO_{1/2})_{1.6}(SiO_{4/2}), and (HMe₂SiO_{1/2})_{1.8}(SiO_{4/2}).

Methods of preparing organohydrogenpolysiloxane resins are well known in the art, as exemplified in U.S. Pat. No. 4,707,531 to Shirahata; U.S. Pat. No. 5,164,461 to Mitchell et al.; U.S. Pat. No. 5,446,087 to Chizat et al. and U.S. Pat. No. 5,310,843 to Morita.

N-alkenyl carbazole (b) is at least one N-alkenyl carbazole having the formula Cz-(CH₂)ₘ₋₂—CH═CH₂, wherein Cz is N-carbazolyl and m is as defined and exemplified above for the first carbazolyl-functional polysiloxane resin.

Examples of N-alkenyl carbazoles suitable for use as N-alkenyl carbazole (b) include, but are not limited to, carbazoles having the following formulae: CH₂═CH—Cz, CH₂═CH—CH₂—Cz, CH₂═CH—(CH₂)₃—Cz, CH₂═CH—(CH₂)₅—Cz, and CH₂═CH—(CH₂)₈—Cz, wherein Cz is N-carbazolyl.

N-alkenyl carbazole (b) can be a single N-alkenyl carbazole or a mixture comprising two or more different N-alkenyl carbazoles, each having the formula Cz—(CH₂)ₘ₋₂—CH═CH₂, wherein Cz and m are as defined and exemplified above.

Methods of preparing N-alkenyl carbazoles are well known in the art. For example, the N-alkenyl carbazoles can be prepared by reacting an ω-alkenyl bromide having the formula Br—(CH₂)ₘ₋₂—CH═CH₂ with sodium carbazole, as described by Heller et al. (Makromol. Chem., 1964, 73, 48).

Alkenyl silane (c) is at least one alkenyl silane having a formula selected from Z₃₋ₙR¹ₙSi—Y—CR³═CH₂ and Z₃₋ₙR¹ₙSi—CR³═CH₂, wherein R¹, R³, Y, Z, and n are as defined and exemplified above for the first carbazolyl-functional polysiloxane resin.

Examples of alkenyl silanes suitable for use as alkenyl silane (c) include, but are not limited to, silanes having the following formulae: CH₂═C(Me)—C(═O)—OCH₂CH₂CH₂Si(OMe)₃, CH₂═CH—Si(OAc)₃, CH₂═CH—(CH₂)₉—Si(OMe)₃, CH₂═CH—Si(OAc)₂(OMe), and CH₂═CH—CH₂—Si(OMe)₃, where Me is methyl and OAc is acetoxy.

Alkenyl silane (c) can be a single alkenyl silane or a mixture comprising two or more different alkenyl silanes, each having a formula selected from Z₃₋ₙR¹ₙSi—Y—CR³═CH₂ and Z₃₋ₙR¹ₙSi—CR³═CH₂, wherein R¹, R³, Y, Z, and n are as defined and exemplified above for the first carbazolyl-functional polysiloxane resin.

Methods of preparing alkenyl silanes are well known methods in the art. For example, alkenyl silanes can be prepared by methods such as direct syntheses, Grignard reactions, addition of organosilicon hydrides to alkenes or alkynes, condensation of chloroolefins with organosilicon hydrides, and dehydrohalogenation of haloalkylsilanes. These and other methods are described by W. Noll in Chemistry and Technology of Silicones, Academic Press:New York, 1968.

Hydrosilylation catalyst (d) can be any of the well-known hydrosilylation catalysts comprising a platinum group metal (i.e., platinum, rhodium, ruthenium, palladium, osmium and iridium) or a compound containing a platinum group metal. Preferably, the platinum group metal is platinum, based on its high activity in hydrosilylation reactions.

Preferred hydrosilylation catalysts include the complexes of chloroplatinic acid and certain vinyl-containing organosiloxanes disclosed by Willing in U.S. Pat. No. 3,419,593, which is hereby incorporated by reference. A preferred catalyst of this type is the reaction product of chloroplatinic acid and 1,3-diethenyl-1,1,3,3-tetramethyldisiloxane.

Organic solvent (e) is at least one organic solvent. The organic solvent can be any aprotic or dipolar aprotic organic solvent that does not react with organohydrogenpolysiloxane (a), N-alkenyl carbazole (b), alkenyl silane (c), or the first carbazolyl-functional polysiloxane resin under the conditions of the present method, and is miscible with components (a), (b), (c), and the carbazolyl-functional polysiloxane resin.

Examples of organic solvents include, but are not limited to, saturated aliphatic hydrocarbons such as n-pentane, hexane, n-heptane, isooctane and dodecane; cycloaliphatic hydrocarbons such as cyclopentane and cyclohexane; aromatic hydrocarbons such as benzene, toluene, xylene and mesitylene; cyclic ethers such as tetrahydrofuran (THF) and dioxane; ketones such as methyl isobutyl ketone (MIBK); halogenated alkanes such as trichloroethane; and halogenated aromatic hydrocarbons such as bromobenzene and chlorobenzene. Organic solvent (e) can be a single organic solvent or a mixture comprising two or more different organic solvents, each as defined above.

The reaction can be carried out in any standard reactor suitable for hydrosilylation reactions. Suitable reactors include glass and Teflon-lined glass reactors. Preferably, the reactor is equipped with a means of agitation, such as stirring. Also, preferably, the reaction is carried out in an inert atmosphere, such as nitrogen or argon, in the absence of moisture.

The organohydrogenpolysiloxane resin, N-alkenyl carbazole, alkenyl silane, hydrosilylation catalyst, and organic solvent can be combined in any order. Typically, N-alkenyl carbazole (b) and alkenyl silane (c) are added, either simultaneously or sequentially in any order, to organohydrogenpolysiloxane resin (a), and, optionally organic solvent (e) before the introduction of hydrosilylation catalyst (d). When organic solvent (e) is present, hydrosilylation catalyst (d) is added to the mixture of (a), (b), (c), and (e). When organic solvent (e) is not present, the mixture of (a), (b), and (c) is heated to a temperature sufficient to form a solution, for example 70° C., and hydrosilylation catalyst (d) is added to the melt.

The reaction is typically carried out at a temperature of from 0 to 140° C., alternatively from room temperature (˜23° C.) to 140° C. When the temperature is less than 0° C., the rate of reaction is typically very slow.

The components are typically allowed to react for a period of time sufficient to complete the hydrosilylation reaction. The term “to complete the hydrosilylation reaction” means the carbazolyl-functional polysiloxane resin contains less than about 2 mol % of silicon-bonded hydrogen atoms, as determined by FTIR spectrometry using the method set forth in the Examples below. The reaction time depends on several factors, such as the structures of the organohydrogenpolysiloxane resin, N-alkenyl carbazole, and alkenyl silane, and the temperature. The time of reaction is typically from 0.5 to 48 h at a temperature of from room temperature to 140° C. The optimum reaction time can be determined by routine experimentation using the methods set forth in the Examples section below.

The mole ratio of N-alkenyl carbazole (b) to silicon-bonded hydrogen atoms in organohydrogenpolysiloxane resin (a) is typically from 0.7 to 0.95, alternatively from 0.8 to 0.9. The mole ratio of alkenyl silane (c) to silicon-bonded hydrogen atoms in organohydrogenpolysiloxane resin (a) is typically from 0.05 to 0.3, alternatively from 0.1 to 0.2.

The concentration of hydrosilylation catalyst (d) is sufficient to catalyze the addition reaction of organohydrogenpolysiloxane resin (a) with N-alkenyl carbazole (b) and alkenyl silane (c). Typically, the concentration of hydrosilylation catalyst (d) is sufficient to provide from 0.1 to 1000 ppm of a platinum group metal, alternatively from 1 to 500 ppm of a platinum group metal, alternatively from 5 to 150 ppm of a platinum group metal, based on the combined weight of organohydrogenpolysiloxane resin (a), N-alkenyl carbazole (b), and alkenyl silane (c). The rate of reaction is very slow below 0.1 ppm of platinum group metal. The use of more than 1000 ppm of platinum group metal results in no appreciable increase in reaction rate, and is therefore uneconomical.

The concentration of organic solvent (e) is typically from 0 to 60% (w/w), alternatively from 30 to 60% (w/w), alternatively 40 to 50% (w/w), based on the total weight of the reaction mixture.

The first carbazolyl-functional polysiloxane resin can be recovered from the reaction mixture by adding sufficient quantity of an alcohol to effect precipitation of the polysiloxane resin and then filtering the reaction mixture to obtain the polysiloxane resin. The alcohol typically has from 1 to 6 carbon atoms, alternatively from 1 to 3 carbon atoms. Moreover, the alcohol can have a linear, branched, or cyclic structure. The hydroxy group in the alcohol may be attached to a primary, secondary, or tertiary aliphatic carbon atom. Examples of alcohols include, but are not limited to, methanol, ethanol, 1-propanol, 2-propanol, 1-butanol, 2-butanol, 2-methyl-1-butanol, 1-pentanol, and cyclohexanol.

A second carbazolyl-functional polysiloxane resin according to the present invention comprises units having the formula I and units having the formula III:

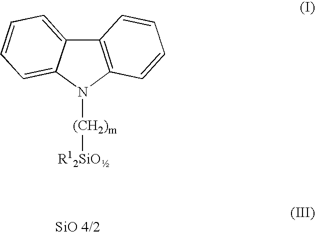

wherein R¹ is C₁ to C₁₀ hydrocarbyl free of aliphatic unsaturation, m is an integer from 2 to 10, and the mole ratio of units (I) to units (III) is from 1.2:1 to 1.8:1. In formula (I), R¹ and m are as defined and exemplified above for the first carbazolyl-functional polysiloxane resin.

The second carbazolyl-functional polysiloxane resin is a copolymer comprising units having formulae (I) and (III), above. The mole ratio of units (I) to units (III) is typically from 1.2:1 to 1.8:1, alternatively from 1.4:1 to 1.8:1, alternatively from 1.6:1 to 1.8:1.

Examples of the second carbazolyl-functional polysiloxane resin include, but are not limited to, polysiloxane resins having the following average formulae:

[Me₂(CzCH₂CH₂CH₂) SiO_{1/2}]_{1.3} (SiO_{4/2}), [Me₂(CzCH₂CH₂CH₂) SiO_{1/2}]_{1.4}(SiO_{4/2}), [Et₂(CzCH₂CH₂CH₂) SiO_{1/2}]_{1.6} (SiO_{4/2}), [Me₂(CzCH₂CH₂CH₂) SiO_{1/2}]_{1.8} (SiO_{4/2}), [Me₂(CzCH₂CH₂) SiO_{1/2}]_{1.6} (SiO_{4/2}), and [Me(Ph)(CzCH₂CH₂CH₂) SiO_{1/2}]_{1.8} (SiO_{4/2}), where Me is methyl, Et is ethyl, Ph is phenyl, and the numerical subscripts denote the relative numbers of moles of the units.

The second carbazolyl-functional polysiloxane resin can be prepared by reacting (a) an organohydrogenpolysiloxane resin consisting essentially of HR¹₂SiO_{1/2} units and SiO_{4/2} units wherein the mole ratio of HR¹₂SiO_{1/2} units to SiO_{4/2} units is from 1.2:1 to 1.8:1, with (b) an N-alkenyl carbazole having the formula Cz—(CH₂)ₘ₋₂—CH═CH₂ in the presence of (d) a hydrosilylation catalyst and, optionally, (e) an organic solvent, wherein Cz is N-carbazolyl and R¹ and m are as defined and exemplified above for the second carbazolyl-functional polysiloxane resin.

Organohydrogenpolysiloxane resin (a), N-alkenyl carbazole (b), hydrosilylation catalyst (d), and organic solvent (e) are as described and exemplified above in the method of preparing the first carbazolyl-functional polysiloxane resin.

The reaction for preparing the second carbazolyl-functional polysiloxane resin can be carried out in the manner described above for preparing the first carbazolyl-functional polysiloxane resin, except the mole ratio of N-alkenyl carbazole (b) to silicon-bonded hydrogen atoms in organohydrogenpolysiloxane resin (a) is typically from 1.0 to 1.2, alternatively from 1.05 to 1.1. Furthermore, the second carbazolyl-functional polysiloxane resin can be recovered from the reaction mixture as described above for the first carbazolyl-functional polysiloxane resin.

A silicone composition according to the present invention comprises:
(A) at least one carbazolyl-functional polysiloxane resin comprising units having the formula I, units having the formula II, and units having the formula III:

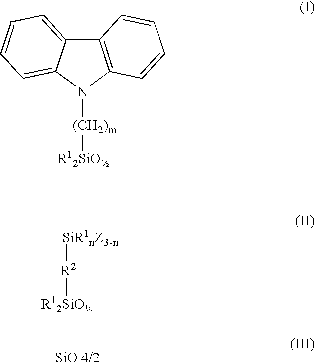

wherein R¹ is C₁ to C₁₀ hydrocarbyl free of aliphatic unsaturation, R² is —CH₂—CHR³— or —CH₂—CHR³—Y—, wherein Y is a divalent organic group and R³ is R¹ or —H, Z is a hydrolysable group, m is an integer from 2 to 10, n is 0, 1, or 2, the mole ratio of units (I) to units (II) is from 4:1 to 9:1, and the mole ratio of units (I) and units (II) combined to units (III) is from 1.2:1 to 1.8:1;
(B) a condensation catalyst; and
(C) an organic solvent.

Component (A) is at least one carbazolyl-functional polysiloxane resin corresponding to the first carbazolyl-functional polysiloxane resin, described and exemplified above.

Component (B) is at least one condensation catalyst. The condensation catalyst can be any condensation catalyst typically used to promote condensation of silicon-bonded hydroxy (silanol) groups to form Si—O—Si linkages. Examples of condensation catalysts include, but are not limited to, tin(II) and tin(IV) compounds such as tin dilaurate, tin dioctoate, and tetrabutyl tin; and titanium compounds such as titanium tetrabutoxide. Component (B) can be a single condensation catalyst or a mixture comprising two or more different condensation catalysts.

The concentration of component (B) is typically from 0.1 to 10% (w/w), alternatively from 0.5 to 5% (w/w), alternatively from 1 to 3% (w/w), based on the total weight of component (A).

Component (C) is at least one organic solvent. Examples of organic solvents include, but are not limited to, saturated aliphatic hydrocarbons such as n-pentane, hexane, n-heptane, isooctane and dodecane; cycloaliphatic hydrocarbons such as cyclopentane and cyclohexane; aromatic hydrocarbons such as benzene, toluene, xylene and mesitylene; cyclic ethers such as tetrahydrofuran (THF) and dioxane; ketones such as methyl isobutyl ketone (MIBK); halogenated alkanes such as trichloroethane; and halogenated aromatic hydrocarbons such as bromobenzene and chlorobenzene.

Component (C) can be a single organic solvent or a mixture comprising two or more different organic solvents, each as defined above. The concentration of the organic solvent is typically from 70 to 99% (w/w), alternatively from 85 to 99% (w/w), based on the total weight of the silicone composition.

The silicone composition of the instant invention is typically prepared by combining components (A), (B), and (C) and any optional ingredients in the stated proportions at ambient temperature.

Mixing can be accomplished by any of the techniques known in the art such as milling, blending, and stirring, either in a batch or continuous process. The particular device is determined by the viscosity of the components and the viscosity of the final silicone composition.

A cured carbazolyl-functional polysiloxane according to the present invention is prepared by curing the silicone composition, described above. The silicone composition can be cured by exposing the composition to moisture at moderate temperature. Cure can be accelerated by application of heat and/or exposure to high humidity. The rate of cure depends on a number of factors, including temperature, humidity, structure of the carbazolyl-functional polysiloxane resin, and nature of the hydrolysable groups. For example, the silicone composition can be cured by exposing the composition to a relative humidity of 30% at a temperature of from about room temperature (23° C.) to about 80° C., for period from 24 to 72 h.

An organic light-emitting diode according to the present invention comprises:
a substrate having a first opposing surface and a second opposing surface;
a first electrode layer overlying the first opposing surface;
a light-emitting element overlying the first electrode layer, the light emitting element comprising
   a hole-transport layer and
   an electron-transport layer, wherein the hole-transport layer and the electron-transport layer lie directly on one another, and one of the hole-transport layer and the electron-transport layer comprises a carbazolyl-functional polysiloxane selected from
      a cured carbazolyl-functional polysiloxane prepared by curing a silicone composition comprising (A) at least one carbazolyl-functional polysiloxane resin comprising units having the formula I, units having the formula II, and units having the formula III:

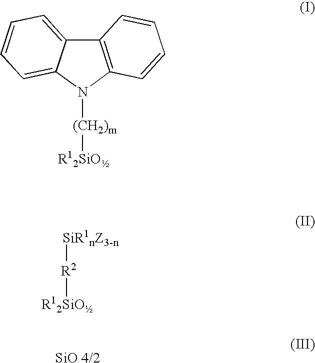

wherein R¹ is C₁ to C₁₀ hydrocarbyl free of aliphatic unsaturation, R² is —CH₂—CHR³— or —CH₂—CHR³—Y—, wherein Y is a divalent organic group and R³ is R¹ or —H, Z is a hydrolysable group, m is an integer from 2 to 10, n is 0, 1, or 2, the mole ratio of units (I) to units (II) is from 4:1 to 9:1, and the mole ratio of units (I) and units (II) combined to units (III) is from 1.2:1 to 1.8:1, (B) a condensation catalyst, and (C) an organic solvent, and
   at least one carbazolyl-functional polysiloxane resin comprising units having the formula I and units having the formula III:

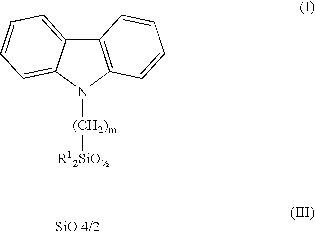

wherein R¹ is C₁ to C₁₀ hydrocarbyl free of aliphatic unsaturation, m is an integer
2 to 10, and the mole ratio of units (I) to units (III) is from 1.2:1 to 1.8:1; and
a second electrode layer overlying the light-emitting element.

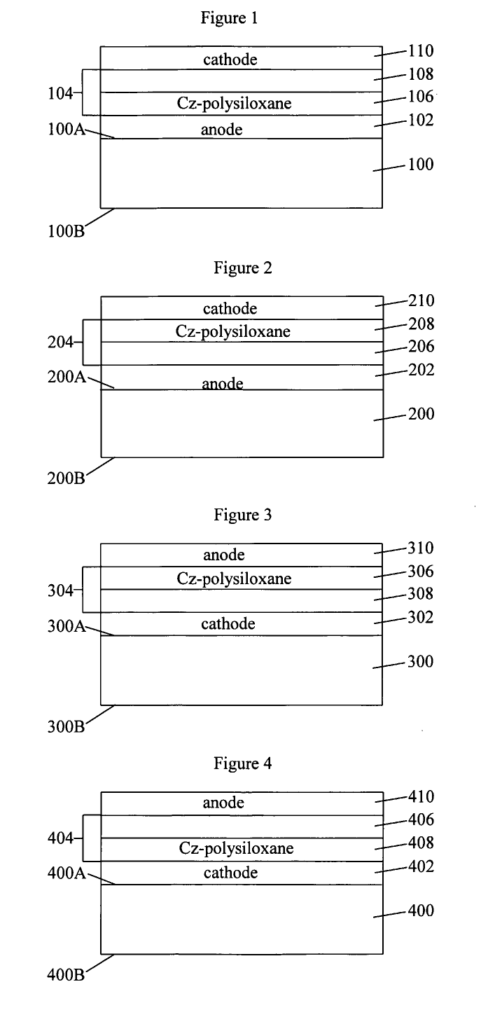

The term “overlying” used in reference to the position of the first electrode layer, light-emitting element, and second electrode layer relative to the designated component means the particular layer either lies directly on the component or lies above the component with one or more intermediary layers there between, provided the OLED is oriented with the substrate below the first electrode layer as shown in FIGS. 1-4. For example, the term “overlying” used in reference to the position of the first electrode layer relative to the first opposing surface of the substrate in the OLED means the first electrode layer either lies directly on the surface or is separated from the surface by one or more intermediate layers.

The substrate can be a rigid or flexible material having two opposing surfaces. Further, the substrate can be transparent or nontransparent to light in the visible region of the electromagnetic spectrum. As used herein, the term “transparent” means the particular component (e.g., substrate or electrode layer) has a percent transmittance of at least 30%, alternatively at least 60%, alternatively at least 80%, for light in the visible region (˜400 to ˜700 nm) of the electromagnetic spectrum. Also, as used herein, the term “nontransparent” means the component has a percent transmittance less than 30% for light in the visible region of the electromagnetic spectrum.

Examples of substrates include, but are not limited to, semiconductor materials such as silicon, silicon having a surface layer of silicon dioxide, and gallium arsenide; quartz; fused quartz; aluminum oxide; ceramics; glass; metal foils; polyolefins such as polyethylene, polypropylene, polystyrene, and polyethyleneterephthalate; fluorocarbon polymers such as polytetrafluoroethylene and polyvinylfluoride; polyamides such as Nylon; polyimides; polyesters such as poly(methyl methacrylate); epoxy resins; polyethers; polycarbonates; polysulfones; and polyether sulfones.

The first electrode layer can function as an anode or cathode in the OLED. The first electrode layer may be transparent or nontransparent to visible light. The anode is typically selected from a high work-function (>4 eV) metal, alloy, or metal oxide such as indium oxide, tin oxide, zinc oxide, indium tin oxide (ITO), indium zinc oxide, aluminum-doped zinc oxide, nickel, and gold. The cathode can be a low work-function (<4 eV) metal such as Ca, Mg, and Al; a high work-function (>4 eV) metal, alloy, or metal oxide, as described above; or an alloy of a low-work function metal and at least one other metal having a high or low work-function, such as Mg—Al, Ag—Mg, Al—Li, In—Mg, and Al—Ca. Methods of depositing anode and cathode layers in the fabrication of OLEDs, such as evaporation, co-evaporation, DC magnetron sputtering, or RF sputtering, are well known in the art.

The light-emitting element comprises a hole-ransport layer and an electron-transport layer, wherein the hole-transport layer and the electron-transport layer lie directly on one another, and one of the hole-transport layer and the electron-transport layer comprises a carbazolyl-functional polysiloxane, described below. The orientation of the light-emitting element depends on the relative positions of the anode and cathode in the OLED. The hole-transport layer is located between the anode and the electron-transport layer and the electron-transport layer is located between the hole-transport layer and the cathode. The thickness of the hole-transport layer is typically from 20 to 100 nm, alternatively from 30 to 50 nm. The thickness of the electron-transport layer is typically from 20 to 100 nm, alternatively from 30 to 50 nm.

The carbazolyl-functional polysiloxane of the OLED can be a cured carbazolyl-functional polysiloxane prepared by curing a silicone composition comprising the first carbazolyl-functional polysiloxane resin, a condensation catalyst, and an organic solvent. The silicone composition and method of curing the composition are as described above.

Alternatively, the carbazolyl-functional polysiloxane of the OLED can be the second carbazolyl-functional polysiloxane resin, described and exemplified above.

The silicone composition used to prepare the cured carbazolyl-functional polysiloxane, and the second carbazolyl-functional polysiloxane resin can be applied to the first electrode layer, the hole-transport layer, or the electron-transport layer, depending on the configuration of the OLED, using conventional methods such as spin-coating, dipping, spraying, brushing, and printing. The second carbazolyl-functional polysiloxane resin can also be dissolved in an organic solvent prior to application, where the organic solvent is as described above for the silicone composition of the invention.

When the hole-transport layer is a carbazolyl-functional polysiloxane, the electron-transport layer can be any low molecular weight organic compound or organic polymer typically used as an electron-transport, electron-injection/electron-transport, or light-emitting material in OLED devices. Low molecular weight organic compounds suitable for use as the electron-transport layer are well known in the art, as exemplified in U.S. Pat. No. 5,952,778; U.S. Pat. No. 4,539,507; U.S. Pat. No. 4,356,429; U.S. Pat. No. 4,769,292; U.S. Pat. No. 6,048,573; and U.S. Pat. No. 5,969,474. Examples of low molecular weight compounds include, but are not limited to, aromatic compounds, such as anthracene, naphthalene, phenanthrene, pyrene, chrysene, and perylene; butadienes such as 1,4-diphenylbutadiene and tetraphenylbutadiene; coumarins; acridine; stilbenes such as trans-stilbene; and chelated oxinoid compounds, such as tris(8-hydroxyquinolato)aluminum(III), Alq₃. These low molecular weight organic compounds may be deposited by standard thin-film preparation techniques including vacuum evaporation and sublimation.

Organic polymers suitable for use as the electron-transport layer are well known in the art, as exemplified in U.S. Pat. No. 5,952,778; U.S. Pat. No. 5,247,190; U.S. Pat. No. 5,807,627; U.S. Pat. No. 6,048,573; and U.S. Pat. No. 6,255,774. Examples of organic polymers include, but are not limited to, poly(phenylene vinylene)s, such as poly(1,4 phenylene vinylene); poly-(2,5-dialkoxy-1,4 phenylene vinylene)s, such as poly(2-methoxy-5-(2-ethylhexyloxy)-1,4-phenylenevinylene) (MEHPPV), poly(2-methoxy-5-(2-methylpentyloxy)-1,4-phenylenevinylene), poly(2-methoxy-5-pentyloxy-1,4-phenylenevinylene), and poly(2-methoxy-5-dodecyloxy-1,4-phenylenevinylene); poly(2,5-dialkyl-1,4 phenylene vinylene)s; poly(phenylene); poly(2,5-dialkyl-1,4 phenylene)s; poly(p-phenylene); poly(thiophene)s, such as poly(3-alkylthiophene)s; poly(alkylthienylene)s, such as poly(3-dodecylthienylene); poly(fluorene)s, such as poly(9,9-dialkyl fluorine)s; and polyanilines. The organic polymers can be applied by conventional solvent coating techniques such as spin-coating, dipping, spraying, brushing, and printing (e.g., stencil printing and screen printing).

When the electron-transport layer is a carbazolyl-functional polysiloxane, the hole-transport layer can be any organic compound typically used as a hole-transport, hole-injection, or hole-injection/hole-transport material in OLED devices. Organic compounds suitable for use as the hole-transport layer are well known in the art, as exemplified in U.S. Pat. No. 4,720,432; U.S. Pat. No. 5,593,788; U.S. Pat. No. 5,969,474; U.S. Pat. No. 4,539,507; U.S. Pat. No. 6,048,573; and U.S. Pat. No. 4,888,211. Examples of organic compounds include, but are not limited to, aromatic tertiary amines, such as monoarylamines, diarylamines, triarylamines, and tetraaryldiamines; hydrazones; carbazoles; triazoles; imidazoles; oxadiazoles having an amino group; polythiophenes, such as poly(3,4-ethylenedioxythiophene) poly(styrenesulfonate), which is sold under the name Baytron® P by H. C. Starck Inc.; and porhyrinic compounds, such as phthalocyanines and metal-containing phthalocyanines. The organic compounds can be applied by conventional thin-film preparation techniques including vacuum evaporation and sublimation.

The electron-transport layer or the hole-transport layer in the light-emitting layer in the light-emitting element can further comprise a fluorescent dye. Fluorescent dyes suitable for use in OLED devices are well known in the art, as illustrated in U.S. Pat. No. 4,769,292. Examples of fluorescent dyes include, but are not limited to, coumarins; dicyanomethylenepyrans, such as 4-(dicyanomethylene)-2-methyl-6-(p-dimethylaminostyryl)4H-pyran; dicyanomethylenethiopyrans; polymethine; oxabenzanthracene; xanthene; pyrylium and thiapyrylium; cabostyril; and perylene fluorescent dyes.

The second electrode layer can function either as an anode or cathode in the OLED. The second electrode layer may be transparent or nontransparent to light in the visible region. Examples of anode and cathode materials and methods for their formation are as described above for the first electrode layer.

The OLED of the present invention can further comprise a hole-injection layer interposed between the anode and the hole-transport layer, and/or an electron-injection layer interposed between the cathode and the electron-transport layer. The hole-injection layer typically has a thickness of from 5 to 20 nm, alternatively from 7 to 10 nm. Examples of materials suitable for use as the hole-injection layer include, but are not limited to, copper phthalocyanine. The electron-injection layer typically has a thickness of from 0.5 to 5 nm, alternatively from 1 to 3 nm. Examples of materials suitable for use as the electron-injection layer include, but are not limited to, alkali metal fluorides, such as lithium fluoride and cesium fluoride; and alkali metal carboxylates, such as lithium acetate and cesium acetate. The hole-injection layer and the hole-injection layer can be formed by conventional techniques, thermal evaporation.

As shown in FIG. 1, a first embodiment of an OLED according to the present invention comprises a substrate 100 having a first opposing surface 100A and a second opposing surface 100B, a first electrode layer 102 on the first opposing surface 100A, wherein the first electrode layer 102 is an anode, a light-emitting element 104 overlying the first electrode layer 102, wherein the light-emitting element 104 comprises a hole-transport layer 106 and an electron-transport layer 108 lying directly on the hole-transport layer 106, wherein the hole-transport layer 106 comprises a carbazolyl-functional polysiloxane, and a second electrode layer 110 overlying the light-emitting element 104, wherein the second electrode layer 110 is a cathode.

As shown in FIG. 2, a second embodiment of an OLED according to the present invention comprises a substrate 200 having a first opposing surface 200A and a second opposing surface 200B, a first electrode layer 202 on the first opposing surface 200A, wherein the first electrode layer 202 is an anode, a light-emitting element 204 overlying the first electrode layer 202, wherein the light-emitting element 204 comprises a hole-transport layer 206 and an electron-transport layer 208 lying directly on the hole-transport layer 206, wherein the electron-transport layer 208 comprises a carbazolyl-functional polysiloxane, and a second electrode layer 210 overlying the light-emitting element 204, wherein the second electrode layer 210 is a cathode.

As shown in FIG. 3, a third embodiment of an OLED according to the present invention comprises a substrate 300 having a first opposing surface 300A and a second opposing surface 300B, a first electrode layer 302 on the first opposing surface 300A, wherein the first electrode layer 302 is a cathode, a light-emitting element 304 overlying the first electrode layer 302, wherein the light-emitting element 304 comprises an electron-transport layer 308 and a hole-transport layer 306 lying directly on the electron-transport layer 306, wherein the hole-transport layer 306 comprises a carbazolyl-functional polysiloxane, and a second electrode layer 310 overlying the light-emitting element 304, wherein the second electrode layer 310 is an anode.

As shown in FIG. 4, a fourth embodiment of an OLED according to the present invention comprises a substrate 400 having a first opposing surface 400A and a second opposing surface 400B, a first electrode layer 402 on the first opposing surface 400A, wherein the first electrode layer 402 is a cathode, a light-emitting element 404 overlying the first electrode layer 402, wherein the light-emitting element 404 comprises an electron-transport layer 408 and a hole-transport layer 406 lying directly on the electron-transport layer 408, wherein the electron-transport layer 408 comprises a carbazolyl-functional polysiloxane, and a second electrode layer 410 overlying the light-emitting element 404, wherein the second electrode layer 410 is an anode.

The carbazolyl-functional polysiloxane resins of the present invention exhibit electroluminescence, emitting light when subjected to an applied voltage. Moreover, the polysiloxane resin containing hydrolysable groups can be cured to produce a durable cross-linked polysiloxane. Also, the polysiloxane resins can be doped with small amounts of fluorescent agents to enhance the electroluminescent efficiency and control the color output of the polysiloxanes.

The silicone composition of the present invention can be conveniently formulated as a one-part composition. Moreover, the silicone composition has good shelf-stability in the absence of moisture. Importantly, the composition can be applied to a substrate by conventional high-speed methods such as spin coating, printing, and spraying. Also, the silicone composition can be readily cured by exposure to moisture at mild to moderate temperatures.

The cured carbazolyl-functional polysiloxane prepared by curing the silicone composition of the present invention exhibits electroluminescence. Moreover, the cured polysiloxane has good primerless adhesion to a variety of substrates. The cured polysiloxane also exhibits excellent durability, chemical resistance, and flexibility at low temperatures. Additionally, the cured polysiloxane exhibits high transparency, typically at least 95% transmittance at a thickness of 100 nm, in the visible region of the electromagnetic spectrum. Importantly, the cured polysiloxane is substantially free of acidic or basic components, which are detrimental to the electrode and light-emitting layers in OLED devices.

The OLED of the present invention exhibits good resistance to abrasion, organic solvents, moisture, and oxygen. Moreover, the OLED exhibits high quantum efficiency and photostability.

The OLED is useful as a discrete light-emitting device or as the active element of light-emitting arrays or displays, such as flat panel displays. OLED displays are useful in a number of devices, including watches, telephones, lap-top computers, pagers, cellular phones, digital video cameras, DVD players, and calculators.

### EXAMPLES

The following examples are presented to better illustrate the carbazolyl-functional polysiloxane resins, silicone composition, and OLED of the present invention, but are not to be considered as limiting the invention, which is delineated in the appended claims. Unless otherwise noted, all parts and percentages reported in the examples are by weight. The following methods and materials were employed in the examples:

### Determination of Molecular Weights

Number-average and weight-average molecular weights (Mₙ and M_{w}) of carbazolyl-functional polysiloxane resins were determined by gel permeation chromatography (GPC) using a PLgel (Polymer Laboratories, Inc.) 5-μm column at room temperature (˜23° C.), a THF mobile phase at 1 mL/min, and a refractive index detector. Polystyrene standards were used for linear regression calibrations.

### Infrared Spectra

Infrared spectra of carbazolyl-functional polysiloxane resins were recorded on a Perkin Elmer Instruments 1600 FT-IR spectrometer. An aliquot of a reaction mixture containing the polysiloxane was dissolved in THF or toluene to achieve a concentration of approximately 10%. A drop of the solution was applied to a NaCl window and the solvent was evaporated under a stream of dry nitrogen to form a thin film of the polysiloxane.

### Film Thickness

The thickness of carbazolyl-functional polysiloxane films was determined using a KLA-Tencor AS-500 surface profiler. Before measurement, a section of the film (2-3 mm wide and 4-5 mm long) was removed, exposing the substrate. Film thickness was measured at the step between the coated and uncoated surfaces of the substrate. The reported values for thickness, expressed in units of microns (μm), represent the average of three measurements performed on different regions of the same substrate.

### Method of Cleaning ITO-Coated Glass Substrates

ITO-coated glass slides (Thin Film Technology, Inc., Buellton, Calif.) having a surface resistance of 10 Ω/square were cut into 25-mm square substrates. The substrates were immersed in an ultrasonic bath containing a solution consisting of 1% Alconox powdered cleaner (Alconox, Inc.) in water for 10 min and then rinsed with deionized water. The substrates were then immersed sequentially in the each of the following solvents with ultrasonic agitation for 10 min in each solvent: isopropyl alcohol, n-hexane, and toluene. The glass substrates were then dried under a stream of dry nitrogen.

### Formation of Polysiloxane Films

Carbazolyl-functional polysiloxane resin films were formed by depositing a solution of the polysiloxane on the substrate and casting it into a thin film using a CHEMAT Technology Model KW-4A spin-coater operating at a speed of 3000 rpm for 20 seconds.

### Deposition of Organic Films and SiO in OLEDs

Thin films of copper phthalocyanine, Alq₃, and silicon monoxide (SiO) were deposited by thermal evaporation using a BOC Edwards Auto 306 high vacuum deposition system equipped with a crystal balance film thickness monitor. The substrate was placed in a rotary sample holder positioned above the source and covered with the appropriate mask. The source was prepared by placing a sample of the organic compound or SiO in an aluminum oxide crucible. The crucible was then positioned in a tungsten wire spiral. The pressure in the vacuum chamber was reduced to 2.0×10⁻⁶ mbar. The substrate was allowed to outgas for at least 30 minutes at this pressure. The organic compound or SiO film was deposited by heating the source via the tungsten filament while rotating the sample holder. The deposition rate (0.1 to 0.3 nm per second) and the thickness of the film were monitored during the deposition process.

### Deposition of Metal Films in OLEDs

Aluminum and lithium fluoride films were deposited by thermal evaporation under an initial vacuum of 10⁻⁶ mbar using a BOC Edwards model E306A Coating System equipped with a crystal balance film thickness monitor. The source was prepared by placing the metal in an aluminum oxide crucible and positioning the crucible in a tungsten wire spiral, or by placing the metal directly in a tungsten basket. When multiple layers of different metals were required, the appropriate sources were placed in a turret that could be rotated for deposition of each metal. The deposition rate (0.1 to 0.3 nm per second) and the thickness of the film were monitored during the deposition process.

### Turn-on Voltage, Brightness, and Relative Efficiency

A sample chamber was constructed using a black plastic box connected to a dry nitrogen line. A sample holder in the box had 5 metal contact pins matching the relative positions of the OLED electrodes on the glass substrates. These metal pins were connected to a Keithley 2400 source meter, through which a given voltage (0.5 V) was applied and the current was measured. In front of the OLED, a photodiode detector was mounted in alignment with the OLED. The photodiode was connected with an International Light IL1700 Radiometer that measured the signal produced by the photodiode. Brightness and relative efficiency were measured at 20 V and 500 cd/cm², respectively.

### Electroluminescent Spectra of OLEDs

Electroluminescent spectra of OLEDs were determined using a Fluorlog II Single Grating Spectrofluorometer. The OLED was fixed in the center of the sample chamber of the spectrofluorometer and the excitation source was covered with a black panel during the measurement. A voltage was applied to the OLED using a source meter, and the spectrum of emitted light from the OLED was recorded with the spectrofluorometer. From a plot of intensity versus wavelength, the wavelength (λₘₐₓ) of emitted light at maximum intensity and the half-peak width (PW₅₀) at maximum intensity were measured for the OLED.

### Example 1

### Preparation of a Carbazolyl-Functional MQ Resin

N-Allylcarbazole (8.07 g, 0.039 mol), 3.4 g of an organohydrogenpolysiloxane resin consisting essentially of H(CH₃)₂SiO_{1/2} units and SiO_{4/2} units, wherein the mole ratio of H(CH₃)₂SiO_{1/2} units to SiO_{4/2} units is about 1.8, and 3 g of anhydrous toluene were combined in a dry flask equipped with a rubber septum. After the flask was purged with dry nitrogen, 0.013 g of a solution consisting of 0.31% of 1,3-divinyl-1,1,3,3-tetramethyldisiloxane and 0.19% of a platinum(IV) complex of 1,3-divinyl-1,1,3,3-tetramethyldisiloxane in 2-propanol was added to the flask using a syringe. The flask was placed in an oil bath and heated at 60° C. for 3 h and then an aliquot was withdrawn for FTIR analysis. The FTIR spectrum showed an absorption for residual Si—H functional groups. A second portion (0.5 g, 2.4 mmol) of N-allylcarbazole was added to the mixture. The flask was vented, continuously purged with nitrogen, and the mixture was heated at 130° C. for 0.5 h. The crude product was dissolved in a minimal amount (˜5 ml) of electronic grade toluene and the carbazolyl-functional polysiloxane resin was precipitated by addition of 20 mL of electronic grade 2-propanol. After allowing the mixture to stand for 5 h at room temperature, the solvent was decanted from the flask. The dissolution/precipitation process was repeated three times. The final precipitate was heated at 140-150° C. in a vacuum oven under argon for 10 min and under vacuum (˜133 Pa) for 1 h. The carbazolyl-functional polysiloxane resin had a number average molecular weight of 981 and a polydispersity of 1.05. An FTIR spectrum of the product showed no residual Si—H groups. The ²⁹Si NMR spectrum of the product shows signals at −108.4 ppm and 10 ppm, corresponding to SiO_{4/2} units and —CH₂(CH₃)₂SiO_{1/2} units, respectively.

### Example 2

### Preparation of a Carbazolyl-Functional MQ Resin

N-Allylcarbazole (4.07 g, 0.020 mol), 1.7 g of an organohydrogenpolysiloxane resin consisting essentially of H(CH₃)₂SiO_{1/2} units and SiO_{4/2} units, wherein the mole ratio of H(CH₃)₂SiO_{1/2} units to SiO_{4/2} units is about 1.8, 0.2 g (0.81 mmol) of 3-methacryloyloxypropyltrimethoxysilane, and 6 g of anhydrous toluene were combined in a dry flask equipped with a rubber septum. After the flask was purged with dry nitrogen, 0.06 g of a solution consisting of 0.31% of 1,3-divinyl-1,1,3,3-tetramethyldisiloxane and 0.19% of a platinum(IV) complex of 1,3-divinyl-1,1,3,3-tetramethyldisiloxane in toluene was added to the flask using a syringe. The flask was placed in an oil bath and heated at 80° C. for 4 h. A second portion (0.3 g, 1.2 mmol) of 3-methacryloyloxypropyltrimethoxysilane was added to the flask and the mixture was heated for an additional 1 h at 80° C. A second portion (1.0 g, 4.9 mmol) of N-allylcarbazole was added to the flask and the mixture was heated at 80° C. for 1 h. The solvent was removed by increasing the temperature to 130° C., venting the flask, and continuously purging the system with nitrogen. The crude product was extracted with 20 mL of electronic grade hexane and then dissolved in a minimal amount (˜3 ml) of electronic grade toluene. The carbazolyl-functional polysiloxane resin was precipitated by addition of ˜20 mL of electronic grade methanol. The dissolution/precipitation process was repeated three times. The final precipitate was purged with dry nitrogen for 10 min to remove residual methanol. The remaining solid was dissolved in 16 mL of anhydrous toluene to produce a concentrated stock solution having a solid content of 29.3%.

### Example 3

### Thin Films of a Cured Carbazolyl-Functional MQ Resin

A solution consisting of 1.5% of the carbazolyl-functional polysiloxane resin of Example 2 and 0.004% of titanium diisopropoxide bis(ethylacetoacetate), which is sold under the name TYZOR DC by DuPont (Wilmington, Del.) in anhydrous toluene was spin-coated on a silicon wafer to produce a film having a thickness of about 40 nm. The film was exposed to air at room temperature for 2 h, and then heated at 80° C. for 30 min.

### Example 4

### Fabrication of OLEDs

Four OLEDs (see figures below) were fabricated as follows: Silicon monoxide (100 nm) was thermally deposited along a first edge of a pre-cleaned ITO-coated glass substrate (25 mm×25 mm) through a mask having a rectangular aperture (6 mm×25 mm). A strip of 3M Scotch brand tape (5 mm×25 mm) was applied along a second edge of the substrate, perpendicular to the SiO deposit. Copper phthalocyanine was thermally deposited on the ITO surface through a mask to form a hole-injection layer (10 nm). A solution consisting of 1.5% of the carbazolyl-functional polysiloxane resin of Example 1 in toluene was spin-coated over the hole-injection layer to form a hole-transport layer having a thickness of 40 nm. The composite was heated in an oven under nitrogen at 80° C. for 30 min and then allowed to cool to room temperature. Tris(8-hydroxyquinolato)aluminum(III), Alq₃, was thermally deposited on the hole-transport layer to form an electron-transport layer (30 nm). The strip of tape was removed from the substrate to expose the anode (ITO), and lithium fluoride was thermally deposited on the electron-transport layer through a mask to form an electron-injection layer (1 nm). The four cathodes were formed by depositing aluminum (150 nm) on the electron-injection layer and SiO deposit through a mask having four rectangular apertures (3 mm×16 mm). The electrical and optical properties of a representative OLED are shown in Table 1.

TABLE 1

| | Turn-On | | Relative | Electroluminescent | |
|---|---|---|---|---|---|
| | Voltage | Brightness | Efficiency | Properties | |
| Example | (V) | (cdm⁻²) | (cdA⁻¹) | λₘₐₓ (nm) | PW₅₀ (nm) |
| 4 | 9.8 | 1678 | 1.1 | 505 | 85 |

That which is claimed is:

1. A carbazolyl-functional polysiloxane resin comprising units having the formula I, units having the formula II, and units having the formula III: 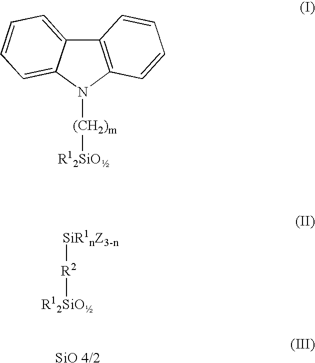
wherein R¹ is C₁ to C₁₀ hydrocarbyl free of aliphatic unsaturation; R² is —CH₂—CHR³— or —CH₂—CHR³—Y—, wherein Y is a divalent organic group and R³ is R¹ or —H; Z is a hydrolysable group; m is an integer from 2 to 10; n is 0, 1, or 2; the mole ratio of units (I) to units (II) is from 4:1 to 9:1; and the mole ratio of units (I) and units (II) combined to units (III) is from 1.2:1 to 1.8:1.

2. The carbazolyl-functional polysiloxane resin according to claim 1, wherein the mole ratio of units (I) to units (II) is from 6:1 to 9:1, and the mole ratio of units (I) and units (II) combined to units (III) is from 1.4:1 to 1.8:1.

3. A carbazolyl-functional polysiloxane resin comprising units having the formula I and units having the formula III: 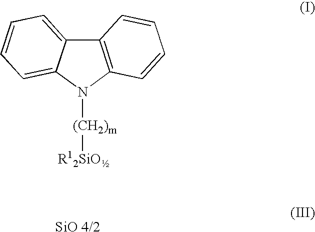
wherein R¹ is C₁ to C₁₀ hydrocarbyl free of aliphatic unsaturation, m is an integer from 2 to 10, and the mole ratio of units (I) to units (III) is from 1.2:1 to 1.8:1.

4. The carbazolyl-functional polysiloxane resin according to claim 3, wherein the mole ratio of units (I) to units (III) is from 1.4:1 to 1.8:1.

5. A silicone composition comprising:
(A) at least one carbazolyl-functional polysiloxane resin comprising units having the formula I, units having the formula II, and units having the formula III: 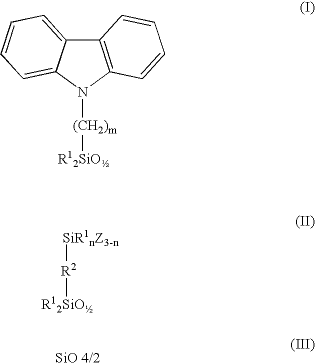
wherein R¹ is C₁ to C₁₀ hydrocarbyl free of aliphatic unsaturation, R² is —CH₂—CHR³— or —CH₂—CHR³—Y—, wherein Y is a divalent organic group and R³ is R¹ or —H, Z is a hydrolysable group, m is an integer from 2 to 10, n is 0, 1, or 2, the mole ratio of units (I) to units (II) is from 4:1 to 9:1, and the mole ratio of units (I) and units (II) combined to units (III) is from 1.2:1 to 1.8:1;
(B) a condensation catalyst; and
(C) an organic solvent.

6. An organic light-emitting diode comprising:
a substrate having a first opposing surface and a second opposing surface;
a first electrode layer overlying the first opposing surface;
a light-emitting element overlying the first electrode layer, the light emitting element comprising
a hole-transport layer and
an electron-transport layer, wherein the hole-transport layer and the electron-transport layer lie directly on one another, and one of the hole-transport layer and the electron-transport layer comprises a carbazolyl-functional polysiloxane selected from
a cured carbazolyl-functional polysiloxane prepared by curing a silicone composition comprising (A) at least one carbazolyl-functional polysiloxane resin comprising units having the formula I, units having the formula II, and units having the formula III: 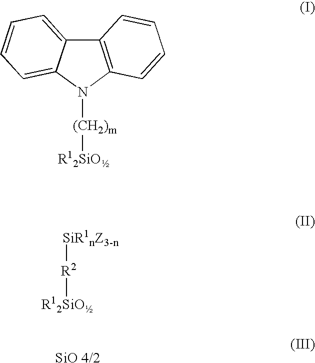
wherein R¹ is C₁ to C₁₀ hydrocarbyl free of aliphatic unsaturation, R² is —CH₂—CHR³— or —CH₂—CHR³—Y—, wherein Y is a divalent organic group and R³ is R¹ or —H, Z is a hydrolysable group, m is an integer from 2 to 10, n is 0, 1, or 2, the mole ratio of units (I) to units (II) is from 4:1 to 9:1, and the mole ratio of units (I) and units (II) combined to units (III) is from 1.2:1 to 1.8:1, (B) a condensation catalyst, and (C) an organic solvent, and
at least one carbazolyl-functional polysiloxane resin comprising units having the formula I and units having the formula III: 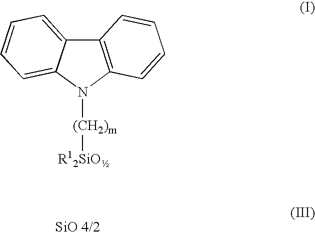
wherein R¹ is C₁ to C₁₀ hydrocarbyl free of aliphatic unsaturation, m is an integer from 2 to 10, and the mole ratio of units (I) to units (III) is from 1.2:1 to 1.8:1; and
a second electrode layer overlying the light-emitting element.

7. The organic light-emitting diode according to claim 6, wherein the hole-transport layer is a carbazolyl-functional polysiloxane.

8. The organic light-emitting diode according to claim 6, wherein the electron-transport layer is a carbazolyl-functional polysiloxane.
